(19) United States
(12) Patent Application Publication
(10) Pub. No.: US 2006/0216880 A1
(43) Pub. Date: Sep. 28, 2006

(54) FINFET devices and methods of fabricating FINFET devices

(76) Inventor: Hiroyuki Suto, Kanagawa-ken (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/384,482

(22) Filed: Mar. 21, 2006

(30) Foreign Application Priority Data
Mar. 25, 2005 (JP) 2005-089483

(51) Int. Cl. H01L 21/8234; H01L 21/336

(52) U.S. Cl. 438/197

(57) ABSTRACT

A semiconductor device includes a plurality of fins formed over the substrate in parallel, the fins including a first fin and a second fin adjacent to the first fin, a gate electrode formed over the substrate, the gate electrode covering a portion of the fins, and a semiconductor layer formed over the fins, the semiconductor layer electrically connecting the first fin and the second fin, the semiconductor layer and the fins forming a source region and a drain region including an impurity ion.

### CROSS REFERENCE TO THE RELATED APPLICATION

This application is based upon and claims the benefit of priority from the prior Japanese Application No. 2005-89483, filed Mar. 25, 2005, the entire contents of which are incorporated herein by reference.

### FIELD OF THE INVENTION

This invention relates to FINFET devices and methods of fabricating FINFET devices. More particularly, the invention pertains to a FINFET device including fins and a method of making the same.

### BACKGROUND OF THE INVENTION

Recently, performance for a miniaturization of a semiconductor device, such as a logical circuit and a memory or the like, is remarkable. Such high performance can be achieved by shortening a gate length and thinning a gate insulating film, based on so-called a scaling rule in Metal Insulator Semiconductor Field Effect Transistor (MISFET).

It is important to address a short channel effect in MISFET with the gate length of 30 nm or less. As one solution, there is a double gate type fin FET of three dimensions MISFET, which forms a projection that thinly fabricates a silicon substrate and forms a gate electrode on the top and both sides of the fin. The channel region is formed in both sides of the fins in the fin FET by applying a gate voltage to the gate electrode.

However, the channel width is decided by the height of the fin in a single fin FET, which forms two gate electrodes to both sides of a single fin. Therefore, there is a problem of unsuitable to the semiconductor device that applies a strong current because the channel width is narrow when the height of the fin is low. However, it is difficult to increase the height of the fin.

In Yang-Kyu Choi's “Sub-20 nm CMOS FinFET Technologies” IEDM Tech. Dig., IEEE, pp. 421-424, 2001, a double gate type multi-fin FET having two or more fins to enlarge the channel width is disclosed. In this multi-fin FET, two or more fins are arranged in parallel and are connected with impurity diffused source and drain regions. And the gate electrode is formed on the fins between the impurity diffused source and drain regions in the direction perpendicular to the fins.

However, a parasitic resistance and a parasitic capacitance increase in this multi-fin FET, since the distance between the fins and the width of fin is very narrow. Although the method of forming a Ge layer selectivity on the fins is shown to decrease the parasitic resistance, the parasitic resistance cannot be sufficiently decreased even by this method.

In a conventional process of fabricating the multi-fin FET, the fins and the impurity diffused source and drain regions are formed, and a gate electrode is formed on the fins using lithography. Therefore, since the distance between the source region and the channel region is different from the distance between the drain region and the channel region when the gate electrode is formed, the resistance between the source region and the channel region is different from the resistance between the drain region and the channel region. This causes degradation of operational characteristics of LSI (Large Scale Integration circuit).

### SUMMARY OF THE INVENTION

One or more of the problems outlined above may be addressed by embodiments of the invention. Broadly speaking, systems and methods are provided to identify the power usage characteristics of software programs and using the information to determine the manner in which the software programs will be executed, thereby improving the management of power within the device executing the programs.

A semiconductor devices includes a substrate, a plurality of fins formed over the substrate in parallel, the fins including a first fin and a second fin adjacent to the first fin, a gate electrode formed over the substrate, the gate electrode covering a portion of the fins, and a semiconductor layer formed over the fins, the semiconductor layer electrically connecting the first fin and the second fin, the semiconductor layer and the fins forming a source region and a drain region including an impurity ion.

One embodiment comprises a method of semiconductor devices includes forming a plurality of fins on a substrate in parallel, the fins including a first fin and a second fin adjacent to the first fin, forming a gate electrode over the substrate, the gate electrode covering a portion of the fins, providing a semiconductor layer over the fins, the semiconductor layer electrically connecting the first fin to the second fin, and implanting an impurity ion in the fins and the semiconductor layer to form a source region and a drain region.

Numerous additional embodiments are also possible. Additional objects and advantages of the invention will be set forth in part in the description which follows, and in part will be obvious from the description, or may be learned by practice of the invention. The objects and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF DRAWINGS

Objects and advantages of the invention may become apparent upon reading the following detailed description and upon reference to the accompanying drawings.

FIG. 1 is a top view of a semiconductor device according to a first embodiment of the invention.

FIG. 2A is a sectional view of the semiconductor device taken along line A-A′ of FIG. 1 according to a first embodiment of the invention.

FIG. 2B is a sectional view of the semiconductor device taken along line B-B′ of FIG. 1 according to a first embodiment of the invention.

FIG. 2C is a sectional view of the semiconductor device taken along line C-C′ of FIG. 1 according to a first embodiment of the invention.

FIG. 2D is a sectional view of the semiconductor device taken along line D-D′ of FIG. 1 according to a first embodiment of the invention.

FIG. 3 is a perspetive view illusrating a method of making the semiconductor device according to a first embodiment of the invention.

FIG. 4A is a sectional view illusrating a method of making the semiconductor device taken along line A-A′ of FIG. 3 according to a first embodiment of the invention.

FIG. 4B is a sectional view illusrating a method of making the semiconductor device taken along line B-B′ of FIG. 3 according to a first embodiment of the invention.

FIG. 4C is a sectional view illusrating a method of making the semiconductor device taken along line C-C′ of FIG. 3 according to a first embodiment of the invention.

FIG. 4D is a sectional view illusrating a method of making the semiconductor device taken along line D-D′ of FIG. 3 according to a first embodiment of the invention.

FIG. 5 is a top view illusrating a method of making a semiconductor device according to a first embodiment of the invention.

FIG. 6A is a sectional view illusrating a method of making the semiconductor device taken along line A-A′ of FIG. 5 according to a first embodiment of the invention.

FIG. 6B is a sectional view illusrating a method of making the semiconductor device taken along line B-B′ of FIG. 5 according to a first embodiment of the invention.

FIG. 6C is a sectional view illusrating a method of making the semiconductor device taken along line C-C′ of FIG. 5 according to a first embodiment of the invention.

FIG. 6D is a sectional view illusrating a method of making the semiconductor device taken along line D-D′ of FIG. 5 according to a first embodiment of the invention.

FIG. 7 is a top view illusrating a method of making a semiconductor device according to a first embodiment of the invention according to a first embodiment of the invention.

FIG. 8A is a sectional view illusrating a method of making the semiconductor device taken along line A-A′ of FIG. 7 according to a first embodiment of the invention.

FIG. 8B is a sectional view illusrating a method of making the semiconductor device taken along line B-B′ of FIG. 7 according to a first embodiment of the invention.

FIG. 8C is a sectional view illusrating a method of making the semiconductor device taken along line C-C′ of FIG. 7 according to a first embodiment of the invention.

FIG. 8D is a sectional view illusrating a method of making the semiconductor device taken along line D-D′ of FIG. 7 according to a first embodiment of the invention.

FIG. 9 is a top view illusrating a method of making a semiconductor device according to a first embodiment of the invention according to a first embodiment of the invention.

FIG. 10A is a sectional view illusrating a method of making the semiconductor device taken along line A-A′ of FIG. 9 according to a first embodiment of the invention.

FIG. 10B is a sectional view illusrating a method of making the semiconductor device taken along line B-B′ of FIG. 9 according to a first embodiment of the invention.

FIG. 10C is a sectional view illusrating a method of making the semiconductor device taken along line C-C′ of FIG. 9 according to a first embodiment of the invention.

FIG. 10D is a sectional view illusrating a method of making the semiconductor device taken along line D-D′ of FIG. 9 according to a first embodiment of the invention.

FIG. 11 is a top view illusrating a method of making a semiconductor device according to a first embodiment of the invention.

FIG. 12A is a sectional view illusrating a method of making the semiconductor device taken along line A-A′ of FIG. 11 according to a first embodiment of the invention.

FIG. 12B is a sectional view illusrating a method of making the semiconductor device taken along line B-B′ of FIG. 11 according to a first embodiment of the invention.

FIG. 12C is a sectional view illusrating a method of making the semiconductor device taken along line C-C′ of FIG. 11 according to a first embodiment of the invention.

FIG. 12D is a sectional view illusrating a method of making the semiconductor device taken along line D-D′ of FIG. 11 according to a first embodiment of the invention.

While the invention is subject to various modifications and alternative forms, specific embodiments thereof are shown by way of example in the drawings and the accompanying detailed description. It should be understood that the drawings and detailed description are not intended to limit the invention to the particular embodiments which are described. This disclosure is instead intended to cover all modifications, equivalents and alternatives falling within the scope of the present invention as defined by the appended claims.

### DETAILED DESCRIPTION OF PREFERRED EMBODIMENTS

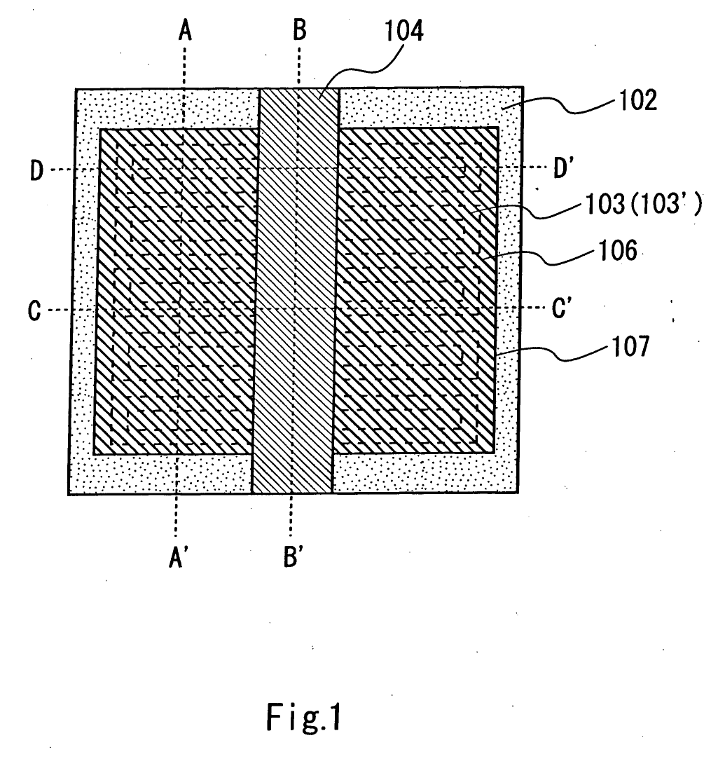

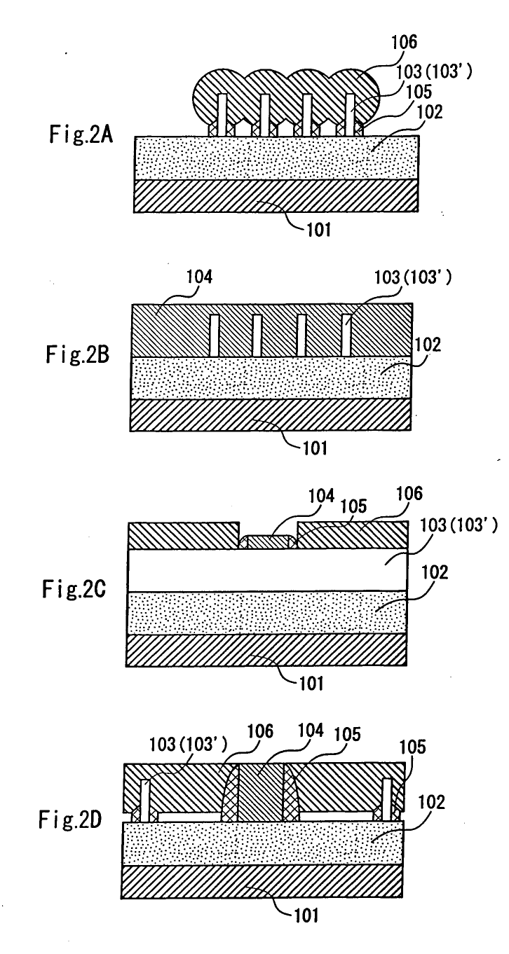

FIGS. 1 and 2A-D illustrate a semiconductor device according to the first embodiment of the invention. The semiconductor device according to the first embodiment shown in FIG. 2A is formed with silicon subtrate 101. Also, the semiconductor device may be formed with BOX (Buried Oxide) layer 102 on silicon substrate 101. Silicon subtrate 101, BOX layer 102, and single Si layer 103′, which is formed into a plurality of fins 103, may be called as a SOI (Silicon On Insulator) substrate. While BOX layer 102 is provided in the first embodiment, BOX layer 102 may not be needed in another embodiment of the semiconductor device.

In the emobodiment shown in FIG. 1 and FIGS. 2A-2D, multiple fins 103 are formed on BOX layer 102 in the SOI layer, and gate electrode 104 is formed on a gate insulating film (not illustrated in the figures) that covers the top and both sides of multiple fins 103. Semiconductor layer 106, which includes a single crystal Si, is formed on top and sides of multiple fins 103. Impurity diffused source and drain regions 107 are formed in fins 103 and semiconductor layer 106, located on both sides of gate electrode 104.

As shown FIG. 1 and FIG. 2A, multiple fins 103 are formed on BOX layer 102 and arranged like stripes at regular intervals. Sidewall spacers 105 are formed on the under and both sides of fins 103. Single crystal silicon layer 106 is radially formed from the top and both sides of fins 103 by crystal growth. Impurity diffused source and drain regions 107 are formed to implant an impurity ion in fins 103 and semiconductor layer 106. A plurality of fins 103 are connected with adjacent fins 103 via semiconductor layer 106. As shown FIG. 2A, semiconductor layer 106 is not formed on the under side of fins, and a space is provided between semiconductor layer 106 and Box layer 102.

In one exmpale, the width of fins 103 may be 10 nm to 15 nm, and the interval of fins 103 may be 50 nm to 55 nm. The film thickness of semiconductor layer 106 may be more than 30 nm, which need to connect with fins 103 each other. Although the edge of fin 103 is connected with the edge of adjacent fin 103 in the embodiment shown in FIG. 1, fins 103 can be formed without being connected with the adjacent fins. Futher, the under side of semiconductor layer 106 between fins 103 can be buried by single crystal Si layer.

As shown FIG. 1 and FIG. 2B, gate electrode 104 is orthogonal to multiple fins 103 and covers a portion of fins 103. In the embodiment shown in FIG. 1, the gate electrode 104 is covering the center portion of fins 3. The gate electrode 104 may cover the top and sides of fins 103. The channel region is formed in fins 103 between gate electrodes 104 by applying a gate voltage. As shown FIG. 2C and FIG. 2D, sidewall spacers 105, which include an insulating film, are formed on both sides of gate electrode 104 between fins 103, providing gate electrode 104 near one of the source region and the drain region. Gate electrode 104 is connected with fins 107 without being connected with single crystal Si layer 106.

The above-described semiconductor device can control drain current between impurity diffused source and drain regions 107 since the channel region is formed in fins 103 between gate electrodes 104 by applying voltage in gate electrode 104.

According to the above-described semiconductor device, single crystal Si layer 106 is radially formed on the top and sides of fins 103 by crystal growth. Thus, since sectional areas of fins 103 increase, the parasitic resistance can be decreased, and drain current can be increased. And since fins 103 are connected with adjacent fins 103, impurity diffused source and drain regions 107 are formed near gate electrode 104. Thus, since it is possible to shorten a distance of fins 103 between impurity diffused source and drain regions 107, the parasitic resistance can be decreased, and fluctuations of source-channel resistance and drain-channel resistance can be decreased.

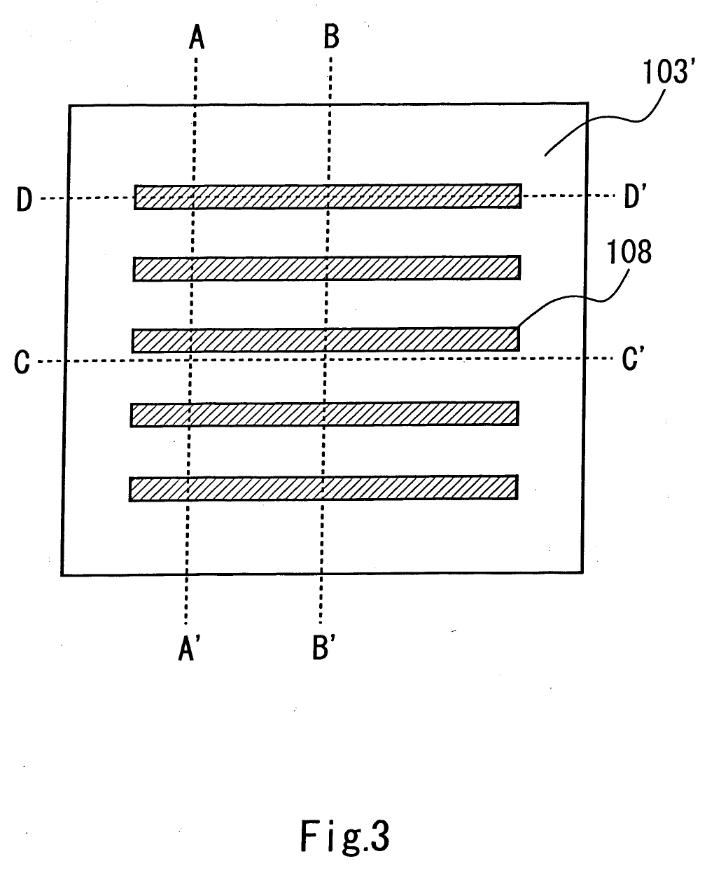

Next, an examplary method of fabricating the above described semiconductor device is shown in FIGS. 3-12.

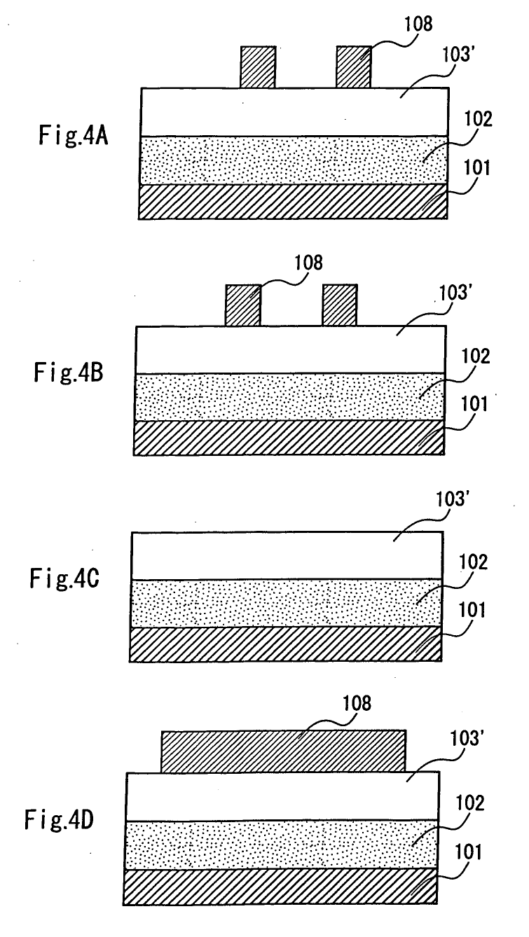

As shown FIG. 3 and FIGS. 4A-4D, an amorphous Si region 108 that becomes dummy patterns 108 to form fins 103 are formed.

As shown FIG. 3 and FIGS. 4A-4D, after a sacrified oxidation film is formed on single crystal SOI layer 103′, amorphous Si film 108 is formed on the sacrified oxidation film using a chemical vapor deposition (CVD). In the embodiment desricbed here, amorphous Si film 108 is used in the dummy pattern; however, other insulating film, for instace, a silicon oxide film or the like can be used.

A resist is formed on amorphous Si film 108 for forming a plurality of dummy patterns which is a long and thin rectangle. And amorphous Si region 108, which becomes dummy patterns of a long and thin rectangle, is formed using lithography and anisotropic etching.

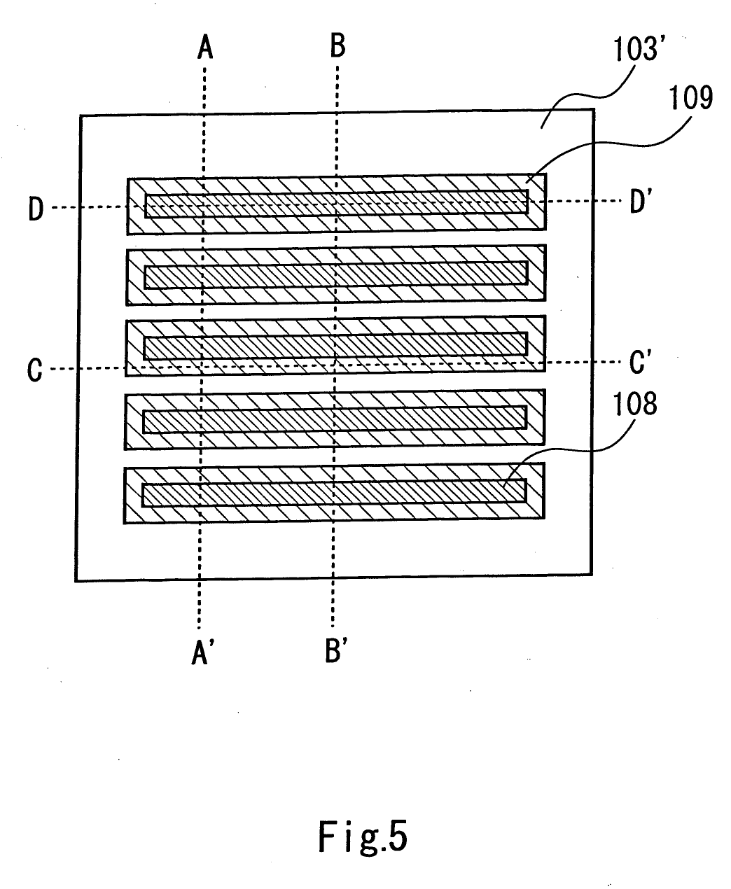

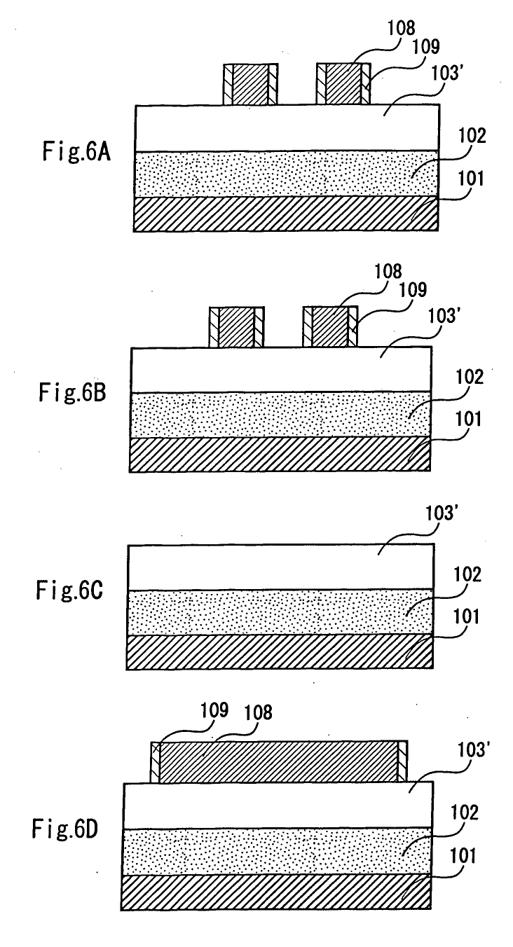

As shown in FIG. 5 and FIGS. 6A-6D, silicon nitride film 109 that becomes mask to form fins 103 is formed.

Silicon nitride film 109 is formed on SOI layer 103′. In this embodiment, the film thickness of silicon nitride film 109 may be 10 nm to 15 nm. Silicon nitride film 109 is formed on the top and both sides of amorphous Si region 108, too. Silicon nitride film 109, other than one on both sides of amorphous Si region 108, is removed using a Chemical Mechanical Polishing (CMP) and an anisotropic etching.

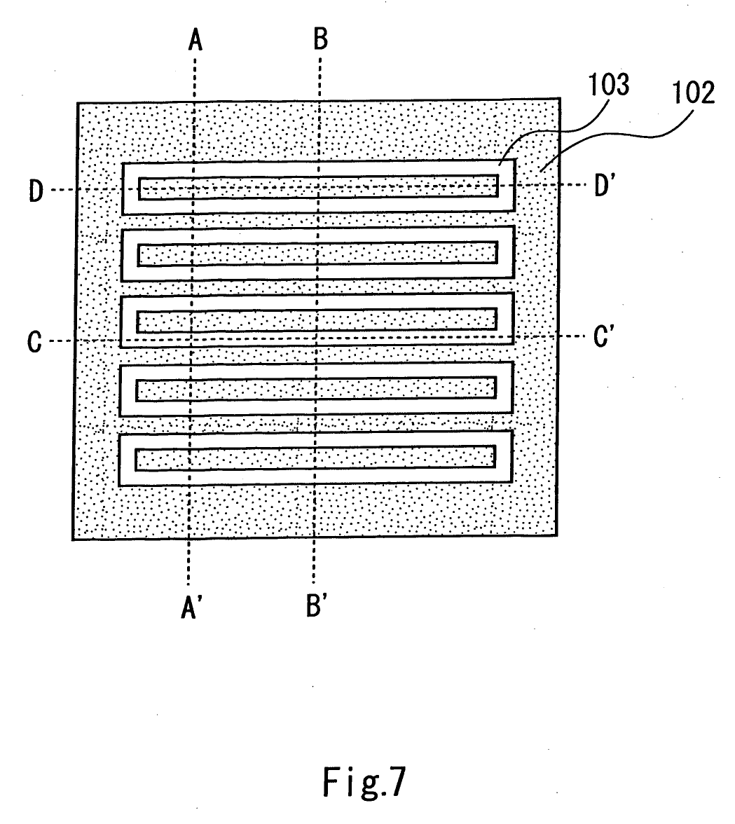

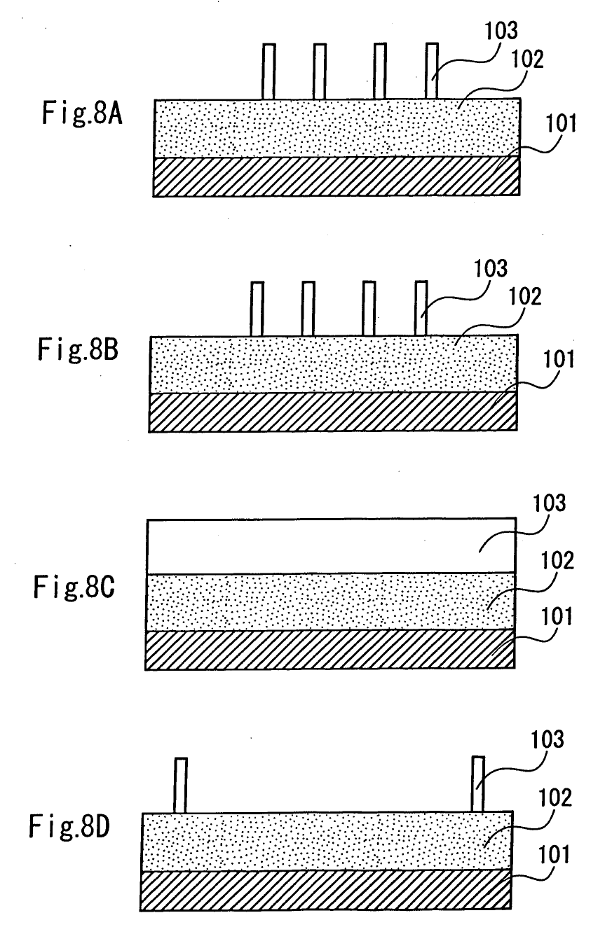

As shown in FIG. 7 and FIG. 8, a plurality of fins 103 is formed.

Amorphous Si region 108 that becomes dummy pattern 108 is removed and silicon nitride film 109 that becomes mask to form fins 103 is formed on SOI layer 103′. SOI layer 103′ is etched to mask silicon nitride film 109 using anisotropic etching. Silicon nitride film 109 is removed using a hot phosphoric acid. Therefore, fins 103, which are arranged at regular intervals, are formed on BOX layer 102.

Here, although fins 103 is formed by forming silicon nitride film 109 on both sides of amorphous Si region 108 and etching single crystal SOI layer 103′ to mask silicon nitride film 109, fins 103 can be formed by forming silicon nitride film on the SOI layer, etching silicon nitride film using a conventional lithography and etching single crystal SOI layer to mask silicon nitride film using an anisotropic etching.

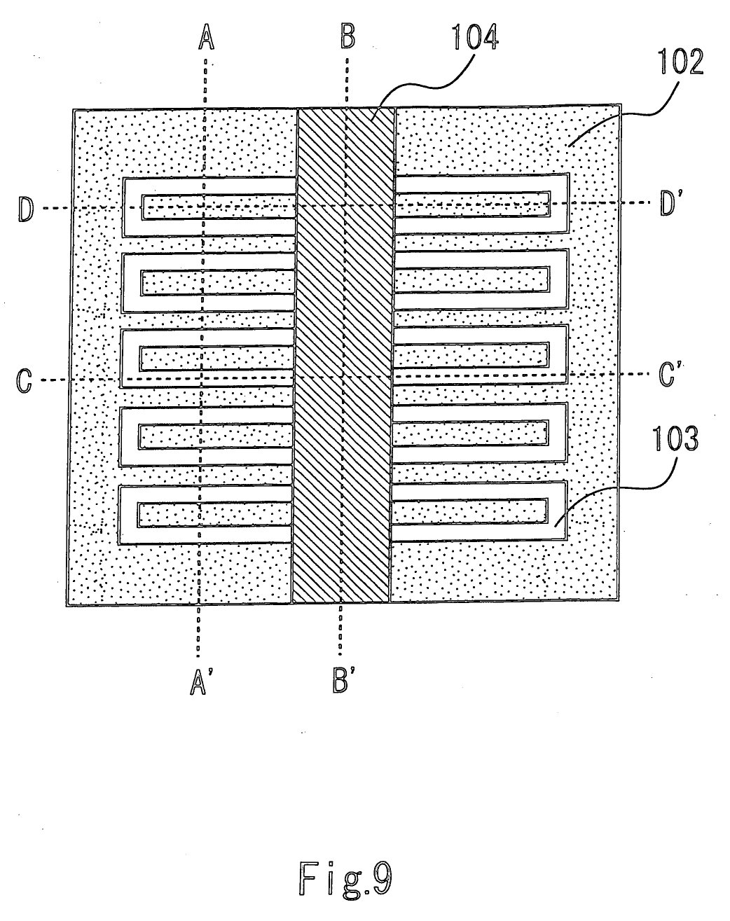

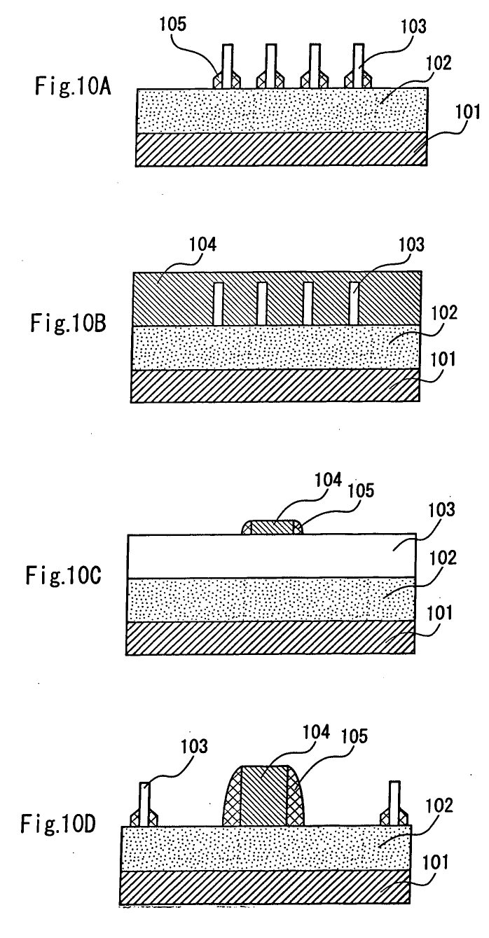

As shown in FIG. 9 and FIG. 10, gate electrode 104 is formed, and sidewall spacers 105 are formed on the both sides of gate electrode 104 and the under side of fins 103. Therefore, sidwall space 105 is juxtaposed with gate electrode 104.

A Silicon oxide film that becomes a gate insulating film is formed on BOX layer 102 and fins 103. Here, as the gate insulating film, a high dielectric constant material, for instance, a silicon oxide nitride (SiON) film and a hafnium silicon oxide nitride (HfSiON) film or the like can be used. Poly-silicon film 104 is formed on the silicon oxide film. Gate electrode 104 is formed in a perpendicular to the longitudinal direction of fins 103 using the lithography and the etching. Here, the gate insulating film and gate electrode 104 is formed to cover the under and both sides of fins 103.

As the material of gate electrode 104, a metal, a metallic compound, silicide or combination of these materials and a poly-silicon or the like can be used.

In the ebodiment, an insulating film is formed on BOX layer 102 and fins 103. Sidewall spacers 105 are formed by etching the insulating film on the both sides of gate electrode 104 and the both under side of fins 103.

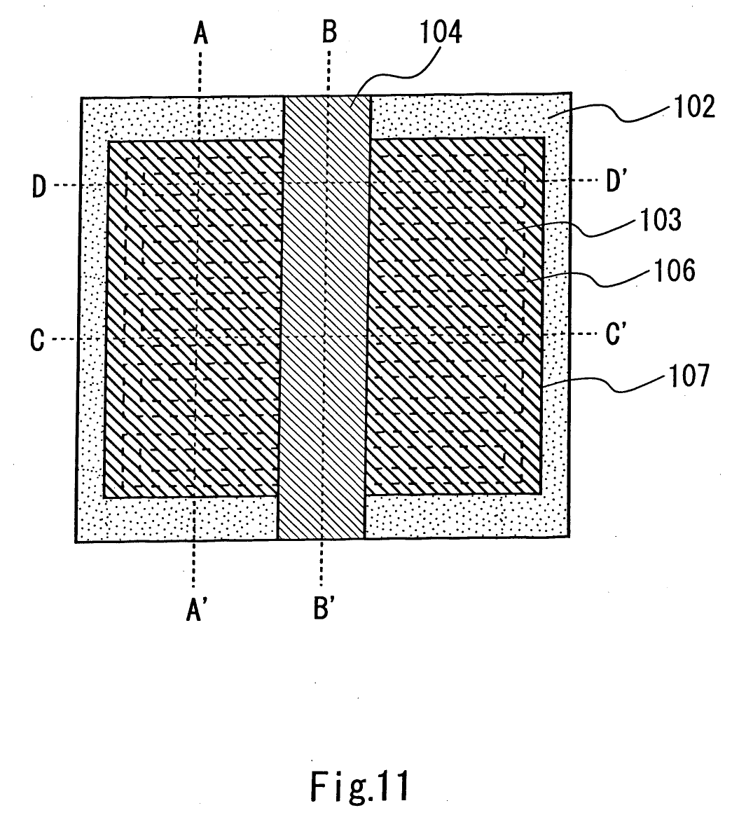

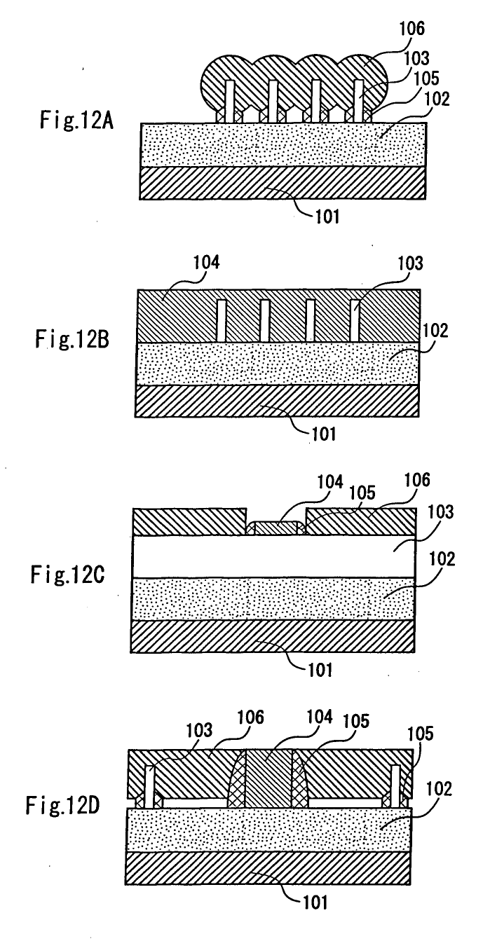

As shown in FIG. 11 and FIG. 12, single Si layer 106 is formed on fins 103, and impurity diffused source and drain regions 107 are formed in fins 103 and single Si layer 106.

As shown in FIG. 11 and FIG. 12, single Si layer 106 that becomes semiconductor layer 106 is formed on the top and both sides of fins 103 located on the both side of gate electrode 104 using selective epitaxial growth method. Here, single crystal Si layer 106 is connected with single crystal Si layers 106 of adjacent fins 103. Since the interval between fins 103 may be 50 nm to 55 nm, the thickness of single crystal Si layer 106 may be formed more than 30 nm by selective epitaxial growth method in this embodiment. Since single crystal Si layer 106 is radially formed on the top and both sides of fins 103 using selective epitaxial growth method, the spaces are provided between semiconductor layer 106 BOX layer 102. The velocity of crystal growth in the top of fins 103 may be different from that in the both side of fins 103. The velocity of crystal growth in the top of fins 103 may be the same velocity in the both side of fins 103.

As the material of semiconductor layer 106, a single crystal Ge, a single crystal SiGe, a poly-crystal Si, a poly-crystal Ge and a poly-crystal SiGe or the like can be used.

Impurity diffused source and drain regions 107 are formed in fins 103 and single Si layer 106 by implanting an impurity ion. Here, although the space is provided between semiconductor layer 106 and BOX layer 102, the space may be buried by single crystal Si layer 106.

Then, the above described semiconductor device may be provided with contact halls and electrodes on gate electrode 104 and impurity diffused source and drain regions 107.

According to the above described method of fabricating the semiconductor device, the fins is connected with the adjacent fins, since the single crystal Si layer is formed on the top and both sides of the fins using selective epitaxial growth method. Therefore, since sectional areas of the fins increase, the parasitic resistance of the fins between the impurity diffused source and drain regions decreases, and drain current increases.

As described to above, after the single crystal Si layer is connected with the single crystal Si layer of the adjacent fins by forming the single crystal Si layer using selective epitaxial growth method, the source and drain regions are formed by implanting an impurity ion in the fins and the single crystal Si layer. This above method forms the impurity diffused source and drain regions to self-align, and the impurity diffused source and drain regions are formed near the gate electrode. Therefore, since it is possible to shorten a distance of fins 103 between impurity diffused source and drain regions 107, the parasitic resistance can be decreased, and fluctuations of source-channel resistance and drain-channel resistance can be decreased.

Since the impurity diffused source and drain regions are formed to self-align by selective epitaxial growth method without fabricating the source and drain regions using lithography and etching, the method of fabricating the conventional fin FET is simplified.

As the semiconductor substrate used SOI substrate, a bulk substrate can be used.

Other embodiment of this invention will be apparent to those skilled in the art from consideration of the specification and practice of the invention disclosed herein. It is intended that the specification and example embodiment be considered as exemplary only, with a true scope and spirit of the invention being indicated by the following.

What is claimed is:

1. A semiconductor device, comprising:
a substrate;
a plurality of fins formed over the substrate in parallel, the fins including a first fin and a second fin adjacent to the first fin;
a gate electrode formed over the substrate, the gate electrode covering a portion of the fins; and
a semiconductor layer formed over the fins, the semiconductor layer electrically connecting the first fin and the second fin, the semiconductor layer and the fins forming a source region and a drain region including an impurity ion.

2. The semiconductor device according to claim 1, further comprising a first spacer between the gate electrode and one of the source region and the drain region.

3. The semiconductor device according to claim 1, wherein the source and the drain region are formed near the gate electrode.

4. The semiconductor device according to claim 1, wherein the semiconductor layer is radially formed on the fins.

5. The semiconductor device according to claim 1, wherein the semiconductor layer is formed on the fins, providing a space between the subtrate and the semiconductor layer.

6. The semiconductor device according to claim 1, wherein the semiconductor layer contains one of single-crystal Si, single-crystal Ge, single-crystal SiGe, poly-Si, poly-Ge, and poly-SiGe.

7. The semiconductor device according to claim 1, wherein the gate electrode is juxtapozed with first sidewall spacers.

8. The semiconductor device according to claim 1, wherein each of the fins is juxtaposed with second sidewall spacers

9. The semiconductor device according to claim 1, further comprising an insulator layer on the substrate.

10. A method of making a semiconductor device, comprising:
forming a plurality of fins on a substrate in parallel, the fins including a first fin and a second fin adjacent to the first fin;
forming a gate electrode over the substrate, the gate electrode covering a portion of the fins;
providing a semiconductor layer over the fins, the semiconductor layer electrically connecting the first fin to the second fin; and
implanting an impurity ion in the fins and the semiconductor layer to form a source region and a drain region.

11. The method according to claim 10, wherein the semiconductor layer is provided by an epitaxial growth method.

12. The method according to claim 10, wherein the source region and the drain region are formed near the gate electrode.

13. The method according to claim 10, further comprising forming a first wall spacer between the gate electrode and one of the source region and the drain region.

14. The method according to claim 10, wherein the semiconductor layer is radially formed over the fins.

15. The method according to claim 10, wherein the semiconductor layer is provided to form a space between the substrate and the semiconductor layer.

16. The method according to claim 10, wherein the semiconductor layer contains one of single-crystal Si, single-crystal Ge, single-crystal SiGe, poly-Si, poly-Ge, and poly-SiGe.

17. The method according to claim 10, further comprising forming sidewall spacers juxtaposing the gate electrode.

18. The method according to claim 10, further comprising forming sidewall spacers justaposing each of the fins.

19. The method according to claim 10, the forming the fins further including providing a SOI substrate, the SOI substrate including the substate, an insulating layer on the substarate, and a silicon layer on the insulating layer, and forming the fins from the silicon layer by etching the silicon layer.
